(19) United States
(12) Patent Application Publication
(10) Pub. No.: US 2026/0047421 A1
(43) Pub. Date: Feb. 12, 2026

(54) STACKED MULTI-LEVEL MEMORY WITH BACKSIDE POWER DISTRIBUTION

(71) Applicant: International Business Machines Corporation, Armonk, NY (US)

(72) Inventors: Rajiv Joshi, Yorktown Heights, NY (US); Joshua M. Rubin, Albany, NY (US); Ruilong Xie, Niskayuna, NY (US)

(21) Appl. No.: 18/798,018

(22) Filed: Aug. 8, 2024

(51) Int. Cl. H01L 23/528; H01L 25/065; H10B 10/00; H10B 80/00

(52) U.S. Cl. CPC H01L 23/5286; H01L 23/5283; H01L 25/0657; H10B 10/12; H10B 80/00; H01L 2225/06541

(57) ABSTRACT

A multi-layered vertically stacked memory device and a method of forming. The vertically stacked memory device includes a hybrid bonding of a single layer memory die having a layer of memory devices and a back-side power delivery circuit network (BSPDN) with another single layer memory die having memory devices and a BSPDN. The BSPDN layers of each single layer memory die are hybrid bonded to form a 2-layer memory die. The structure includes a formed TSV at one side and C4 or solder bumps at an opposite side such that the 2-layer memory dies can be stacked to form a vertically stacked structure having multiple memory device layers. Similarly formed is a 4-layer memory die that can be stacked to form a vertically stacked structure having multiple memory device layers. The vertical stacked memory device of such 2-layer or 4-layer memory dies can be formed over an interposer.

### BACKGROUND

The present application relates to semiconductor technology, and more particularly to a semiconductor memory device including a stacked multi-level Static Random Access Memory (SRAM) including volatile memory (VM) and Non-volatile memory (NVM) such as MRAM, ReRAM, PCM that improves the memory bandwidth.

SRAM is a type of random access memory (RAM) that uses latch circuitry (flip-flop) to store each bit. A typical SRAM cell is made up of six FETs. Each bit in a conventional SRAM is stored on four of the transistors that form two cross-coupled inverters. This storage cell has two stable states which are used to denote 0 and 1. Two additional access transistors serve to control the access to a storage cell during read and write operations. In addition to such six transistor (6T) SRAM, other kinds of SRAM chips use 4T, 8T, 10T or nT, where n is the number of transistors per bit. Providing a SRAM design in a stacked architecture or 3-dimensional (3D) SRAM memory integration schemes is a challenge.

### SUMMARY

A semiconductor memory device and method of forming is provided that includes multiple-level stacked memory dies or memory chiplet dies with power distribution through a backside.

A semiconductor memory device and method of forming is provided that includes multiple-level stacked memory layers with power distribution through the backside and wherein each level has a two-layer memory die stack, one side of the stack having Through-Silicon-Via (TSV) formations and the other side integrates metal pads and connections such as C4 bump features.

A semiconductor memory device and method of forming is provided that includes multiple-level stacked memory layers with power distribution through backside and wherein each level has a two-layer memory die stack, with each memory layer having 3 or more layers of back-end-of-line (BEOL) interconnect at both frontside and backside.

In one aspect, a hybrid bonding is provided between different stacks.

In a further aspect, there is provided a vertically stacked memory structure and method of forming stacked memory dies, where signal wires are provided out from each front-front side bonding, and power wires are provided out from each back-back side bonding.

In one aspect of the present application, a memory device is provided. The memory device comprises: a two or more-layer memory die stack, the two or more-layer memory die stack comprising: a first memory die having a first single layer of memory devices and conductors forming a backside power delivery network; and a second memory die having a second single layer of memory devices and conductors forming a backside power delivery network; wherein the second memory die is flipped in orientation, the first memory die and flipped second memory die are hybrid bonded together so that the backside power delivery network conductors of the first memory die are aligned with and directly bond to the backside power delivery network conductors of the second memory die.

In a further aspect, there is provided a memory device. The memory device comprises: a first two-layer memory die stack comprising: a first memory die having a single layer of memory devices, frontside conductive wires at a die surface for carrying signals, and conductors forming a backside power delivery network; and a second memory die having a single layer of memory devices and conductors forming a backside power delivery network, the second memory die being flipped in orientation, wherein the first memory die and flipped second memory die being hybrid bonded together so that the backside power delivery network conductors of the first memory die are aligned with and directly bond to the backside power delivery network conductors of the flipped second memory die; and a second two-layer memory die stack comprising: a third memory die having a single layer of memory devices, and conductors forming a backside power delivery network; and a fourth memory die having a single layer of memory devices, frontside conductive wires at a die surface for carrying signals, and conductors forming a backside power delivery network, the fourth memory die being flipped in orientation, wherein the third memory die and flipped fourth memory die are hybrid bonded together so that the backside power delivery network conductors of the third memory die are aligned with and directly bond to the backside power delivery network conductors of the flipped fourth memory die; and the first two-layer memory die stack and second two-layer memory die stack being hybrid bonded to form a four (4)-layer memory die stack, the 4-layer memory die stack having the frontside conductive wires at a die surface of the first memory die of the first two-layer memory die stack bonded to the frontside conductive wires at a die surface of the flipped fourth memory die of the second two-layer memory die stack.

In a further aspect, there is provided a memory device. The memory device comprises: a two-layer memory die stack, the two-layer memory die stack comprising: a first memory die having a single layer of memory devices, a frontside interlevel dielectric (ILD) layer above the single layer of memory devices, frontside conductive wires formed at multiple metallization levels in the frontside ILD layer for carrying signals, and conductors forming a backside power delivery network; and a second memory die having a single layer of memory devices, a frontside interlevel dielectric (ILD) layer above the single layer of memory devices, frontside conductive wires formed at multiple metallization levels in the frontside ILD layer for carrying signals, and conductors forming a backside power delivery network, the second memory die being flipped in orientation, the first memory die and flipped second memory die being hybrid bonded together so that the backside power delivery network conductors of the first memory die are aligned with and directly bond to the backside power delivery network conductors of the flipped second memory die.

In addition to providing a memory device, the present application also provides a method of forming the same. The method of the present application will become more apparent be the drawings and detailed discussion section to follow.

### BRIEF DESCRIPTION OF THE DRAWINGS

FIG. 1A illustrates a conceptual cross-sectional view of a 3-D vertically stacked SRAM design layout including a laminate or interposer having formed on a surface thereon an electrically connected stack of multiple memory wafers or memory dies that include a frontside memory layer formed on a first single die and a backside memory layer formed on a second single die that are bonded together according to embodiments herein;

FIG. 1B is a top-down layout view taken along line A-A of FIG. 1A showing the layout view of the memory layer on the hybrid-bonded wafers and including the example locations of power lines and signal lines about the perimeter of the memory array in an embodiment;

FIG. 1C illustrates a further embodiment of the cross-sectional view of the 3-D stacked memory design layout of FIG. 1A. However, further including a formed heat sink structure positioned on top according to an embodiment;

FIG. 2 is a conceptual view depicting a portion of the formed single bonded wafer structure 50 of the vertically stacked memory structures shown in FIGS. 1A-1C that includes bonding of a first wafer or die having memory layer and a second wafer or die having an memory layer according to an embodiment;

FIGS. 3A-3H depict a method for manufacturing the structure shown in FIGS. 1A-1C according to an embodiment;

FIG. 4 depicts a resulting single 2-layer memory die structure formed by the hybrid bonding of two single memory dies including the bonding of the surface of a first single die of FIG. 3G having respective backside power delivery network circuitry connecting a first memory device layout to the surface of a flipped second single die of FIG. 3H having respective backside power delivery network circuitry connecting a second memory device layout according to an embodiment;

FIGS. 5A-5B depict further performed method steps for increasing the size of the vertical stack of memory device wafers and the amount of memory according to a first embodiment;

FIG. 5C shows a simplified view of a formed 2-layer memory die structure according to an embodiment;

FIG. 5D shows a resulting final bonded 3-D vertical stacked structure of multiple 2-layer memory dies shown in FIG. 5C formed on a laminate substrate or interposer or like carrier substrate according to an embodiment;

FIGS. 6A-6C depict a further embodiment for stacking memory wafers to form a bonded 4-layer memory die as a vertical stacked memory structure in an embodiment;

FIG. 6D depicts a cross-sectional view of a formed 8-layer memory die structure resulting from the hybrid bonding of a bottom 4-layer memory die structure of FIG. 6C to a top 4-layer memory die structure of FIG. 6C that provides a total of eight memory device levels in an embodiment;

FIG. 6E shows a resulting final bonded 3-D vertical stack structure of a formed 8-layer memory die structure (stack of memory device wafers) shown in FIG. 6D formed on and electrically connected to laminate substrate or interposer or like carrier substrate in an embodiment;

FIG. 7 depicts an embodiment of a single layer memory die 600 that includes three metal layers (levels) on both frontside and backside of the die in an embodiment;

FIG. 8 depicts a cross-sectional view of a further 3D-stacked memory device structure that is built using the similar methods as shown in FIGS. 6A-6D to form an 8-layer memory die structure according to a further embodiment;

FIG. 9 depicts a cross-sectional view of a further 3D-stacked memory device structure that is built using the similar methods as shown in FIGS. 6A-6D to form an 8-layer memory die structure according to a further embodiment;

FIG. 10 shows a graph depicting a power consumption for a 4 GB memory (in Watts) plotted against a lesser cache memory hardware and is based on example memory L2 Cache hardware measurements, e.g., in 5 nm technology at different activity factors; and

FIG. 11 depicts a view of a further 3D stacked memory device structure that includes stacked chiplets with embedded memory devices built using the methods of the embodiments herein.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The memory structures as referred to herein can include but is not limited to Static Random Access Memory (SRAM) which can include volatile memory (VM) and include Non-volatile memory (NVM) including, but not limited to: magnetic random access memory (MRAM), Resistive random access memory (ReRAM) and phase change memory (PCM). The memory dies can include a chiplet/chiplet package(s) with embedded memory.

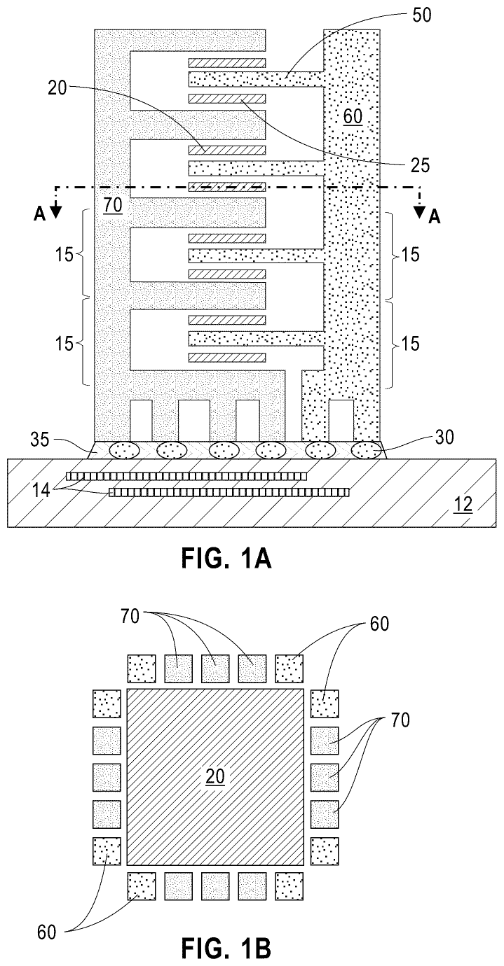

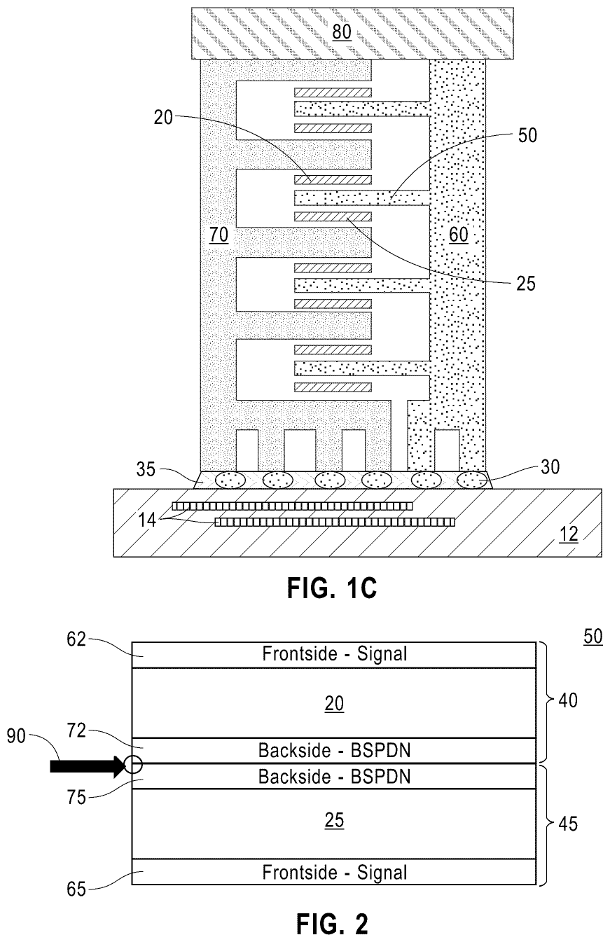

Referring first to FIG. 1A, there is illustrated a conceptual cross-sectional view of a 3-D stacked SRAM design layout 10 including a substrate, a fanout package, a laminate or interposer or like Back-End-Of-Line (BEOL)/carrier wafer structure 12, having formed on a surface thereon and electrically connected to multiple layers 15 of vertically stacked SRAM wafers or dies that each includes a frontside SRAM layer 20 formed on a first single die and a backside SRAM layer 25 formed on a second single die with both first and second dies being hybrid bonded together to form a single 2-layer bonded SRAM device structure 50. As shown in FIG. 1A, the bottommost stacked SRAM layer 15 connects to the laminate or interposer substrate 12 via C4 or solder bumps/pads 30 and the structure is mechanically reinforced and stabilized with an underfill material layer 35. As referred to herein, hybrid bonding refers to one or more of:
wafer-to-wafer (W2W) and die-to-wafer (D2W) bonding. W2W involves the direct bonding of two wafers, whereas D2W refers to the bonding of multiple known dies onto a bottom wafer. In a hybrid bonding process, the wafer surface consists of two materials: metal and dielectric, where during the bonding process, the dies being combined are aligned based on metal and dielectric areas.

In an embodiment depicted in FIG. 1, each SRAM layer 20 on the single bonded wafer structure 50 includes various electrical connections to vertically extended power lines 60 carrying voltage signals, e.g., for powering SRAM transistor devices and other circuitry, and vertically extended signal lines 70, e.g., for carrying data and logic signals to/from various devices and circuits. It is understood that that signal lines and power lines are interchangeable and not necessary at left and right edges of SRAM layer as shown. For example, FIG. 1B is a top-down layout view taken along line A-A of FIG. 1A showing the layout view of the SRAM layer 20 on the hybrid-bonded wafers and including the example locations of power lines 60 and signal lines 70 about the perimeter of the SRAM array. In an embodiment, power goes between back-to-back bonding to the power wires 70 and the signals go between front-to-front bonding to signal wires 70. Both power lines 60 and signal wires 70 extend down to the interposer substrate 12 for electrical connection to circuits and conductors 14 through aligned solder bumps/pads 30.

Referring first to FIG. 1C, illustrates a further embodiment of the cross-sectional view of the 3-D stacked SRAM design layout 10 of FIG. 1A however, further including a formed heat sink structure 80 positioned on top the topmost layer of the vertically stacked SRAM structures.

FIG. 2 is a conceptual view depicting a portion of the formed single bonded wafer structure 50 of the vertically stacked SRAM structures shown in FIGS. 1A-1C that includes a bonding of a first wafer or die 40 having SRAM memory layer 20 and second wafer or die 45 having SRAM memory layer 25. In FIG. 2, the first wafer or die 40 includes the frontside SRAM layer 20 formed on the first wafer and includes, formed on the first wafer, a frontside signal delivery network 62 positioned above and having signal array conductors connecting the SRAM layer memory 20 to peripheral circuits (not shown) and includes a backside power delivery network (BSPDN) 72 formed underneath and electrically connecting to the SRAM memory layer 20 on the first wafer. Similarly, bonded to the first wafer 40 is the second wafer or die 45 which is a flipped version of the first wafer 40, and includes backside SRAM layer 25 formed on the second wafer, frontside signal delivery network 65 positioned above and having signal array conductors (not shown) connecting the SRAM layer memory 25 to peripheral circuits (not shown) and includes a backside power delivery network 75 formed underneath and electrically connecting to the SRAM memory layer 25 on the second wafer. As shown in FIG. 2, the hybrid bonding of first wafer 40 and second wafer 45 connects the backside power delivery network 72 formed on first wafer 40 with the backside power delivery network 75 formed on second wafer 45 and provides a shared lateral power feed input 90 for receiving power signals for powering both the SRAM memory layers 20, 25.

In the structure of FIG. 2, the SRAM memory chips or SRAM dies on bonded frontside SRAM layer 20 and backside SRAM layer 25 can be paired. The pairing of SRAM chips on bonded wafers 40, 45 have improved power integrity and the BSPDN enables wider metal lines since there are no signals in the SRAM array on the BSPDN side. Thus, in the configuration of FIG. 2, the BSPDN lateral power distribution is improved.

Further, different activity levels between SRAM dies enable reduced IR-voltage drop due to the frontside and backside BSPDN layers 72, 75 sharing a lateral power feed 90 and also enable reduced droop due to a shared MIMcap, whereby memory dies/SRAM arrays can be accessed sequentially to benefit from this arrangement.

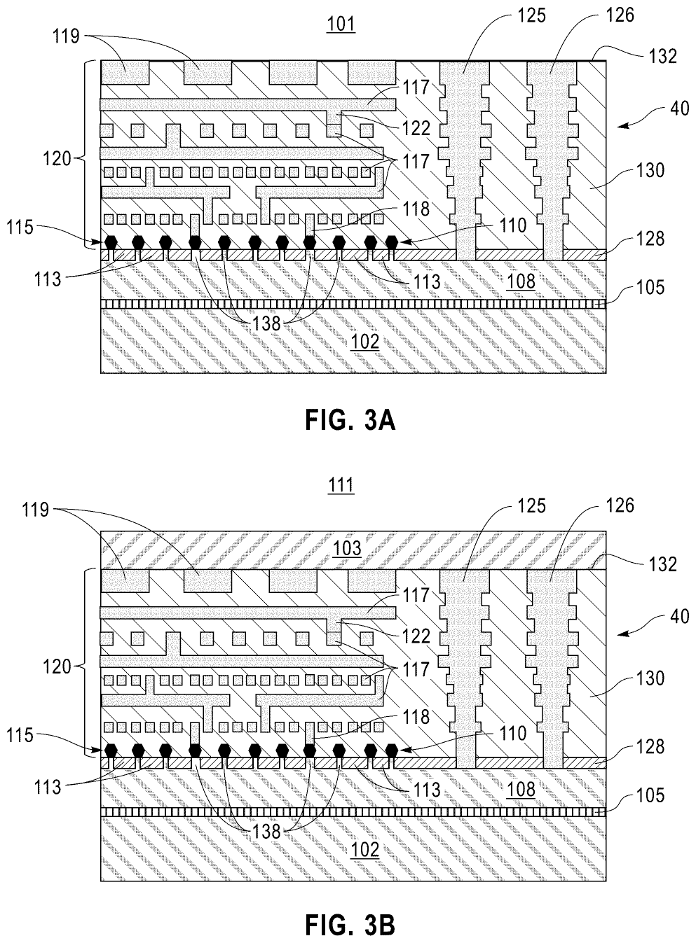

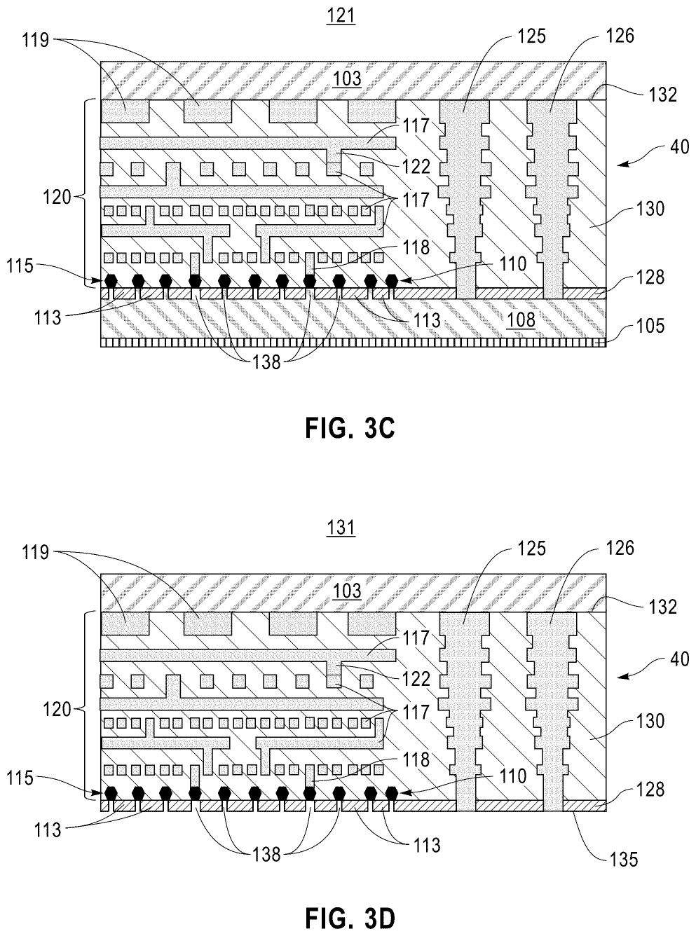

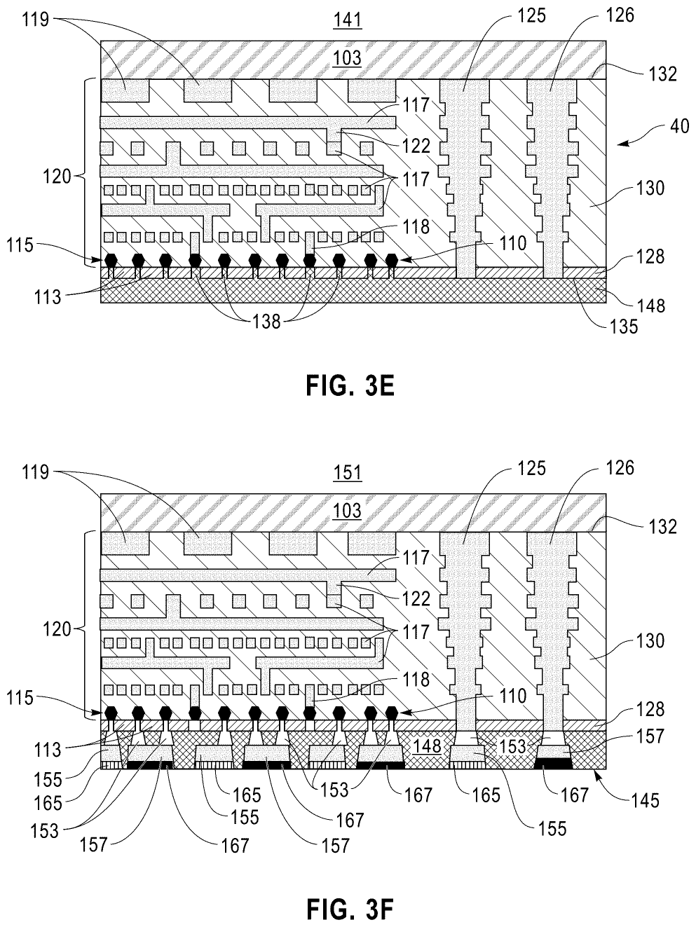

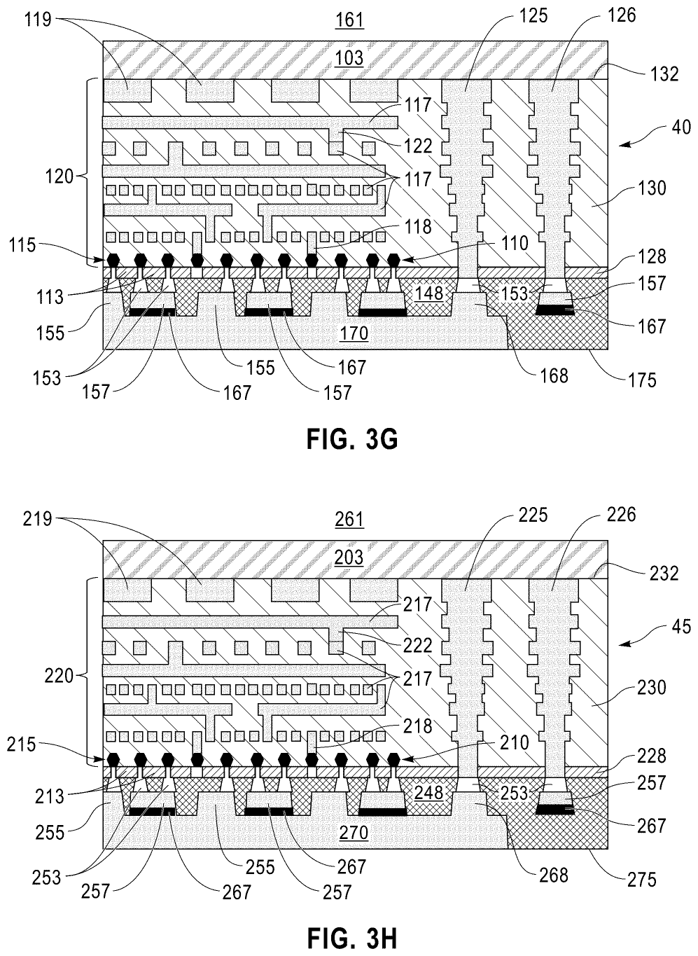

FIGS. 3A-3H depict a method for manufacturing the structure shown in FIGS. 1A-1C. FIG. 3A depicts a cross-sectional view of a first structure 101 resulting from the forming of SRAM device layer (e.g., SRAM memory cell array or cell layout) 110 on the first SRAM device wafer or die 40 and in particular, the forming on a first Si substrate layer 102, an etch stop layer 105 on top of substrate 102 and an epitaxially grown second Si-material containing layer 108 formed above etch stop layer 105. In an embodiment, the semiconductor substrate 102 that can be used in the present application includes at least one semiconductor material having semiconductor properties, e.g., silicon (Si), or a silicon germanium (SiGe) alloy.

Formed above the Si-epi layer 108 is a dielectric material layer 128 that includes a dielectric material having insulating properties. Formed above dielectric material layer 128 is one or more interlevel dielectric (ILD) material layers 130 that is composed of any dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” denotes a dielectric material that has a dielectric constant of less than 4.0 (all dielectric constants mentioned herein are relative to a vacuum unless otherwise noted). Although not shown, the ILD material layer 130 can include a multilayered structure that includes at least two different dielectric materials stacked one atop the other such as, for example, silicon nitride and silicon dioxide. The ILD material layer 130 can be formed by a deposition process such as, for example, chemical vapor deposition (CVD), plasma-enhanced chemical vapor deposition (PECVD), or spin-on coating. A planarization process (including, for example, chemical mechanical polishing (CMP) can be performed after the deposition of the dielectric material that provides ILD material layer 130.

Formed within interlevel dielectric material layer 120 and above dielectric material layer 128 is an SRAM device layer 110 including a horizontal layout of one or multiple array(s) of SRAM (or other types of) non-volatile memory devices 115 where each SRAM device 115 can include multiple Field Effect Transistors (FETs) transistors, e.g., 4, 8, 10 (4T, 8T, 10T SRAM), that each can have formed epitaxially grown source drain terminals (S/D epi) and channel regions. The S/D epi regions can be of a certain conductivity type (i.e., n-type or p-type) and is formed by an epitaxial growth process as known in the art, e.g., molecular beam epitaxy (MBE). In an embodiment, the dielectric material layer 128 formed between a top surface of the epitaxially grown Si-material containing layer 108 and the bottom of the interlevel dielectric material layer 130 includes a series of shallow trench isolation (STI) structures 113 that function to separate and electrically isolate the various epitaxially grown source drain terminal regions of a transistor of a respective SRAM device 115.

As further shown in the structure of FIG. 3A, formed above SRAM device layer 110 and within interlevel dielectric material layers 130 are one or more (e.g., multiple) metallization layers 120 each layer including one or more layers of various metal conductors 117 for connecting to SRAM devices 115 and/or to other devices or peripheral devices/circuits. The metallization layers 120 can also include formed vertically extended conductive vias 118 that electrically a conductor 117 to SRAM devices 115 and/or to other devices or peripheral circuits (not shown). Further included in a metallization layer are conductive via structures 122 that extend from conductors 117 of one metallization level to electrically connect with a conductor 117 laid out on another metallization layer. In an embodiment, the conductive structures 117, 118, can include a word line conductor, e.g., connected to a transistor gate structure (not shown) of SRAM memory device 115 or a bit line conductor, e.g., connected to a S/D epi contact structure.

As further shown in the structure of the first die or wafer 40 is a top layer of conductors 119 which are larger conductive structures, e.g., pads, and include top planarized surfaces co-planar with the top surface 132 of the interlevel dielectric 130. In an embodiment, the conductors 117, 119, and vias 118, 122 can be formed using known BEOL processing techniques that are well known to those skilled in the art. These conductors can consist of any electrically conductive metal-containing material including, but not limited to tungsten (W), titanium (Ti), tantalum (Ta), ruthenium (Ru), zirconium (Zr), cobalt (Co), copper (Cu), aluminum (Al), lead (Pb), platinum (Pt), tin (Sn), silver (Ag), or gold (Au), tantalum nitride (TaN), titanium nitride (TiN), tantalum carbide (TaCₓ), titanium carbide (TiC), titanium aluminum carbide, tungsten silicide (WSi₂), tungsten nitride (WN), ruthenium oxide (RuO₂), cobalt silicide, or nickel silicide. Referring to FIG. 3A, there is shown a result of further forming one or more global communication vias 125, 126 that extend from a top surface 132 of the wafer structure down to the epitaxially grown Si-material containing layer 108 and which contain like electrically conductive metal-containing material.

FIG. 3B depicts a cross-sectional view of an intermediate structure 111 resulting from the bonding of a carrier wafer substrate 103 to the top surface 132 of the intermediate first SRAM layer structure 101 of FIG. 3A. In an embodiment, a wafer-to-wafer bonding procedure is conducted including direct wafer to wafter bond the wafer 101 to carrier wafer substrate 103, e.g., without any additional intermediate layers. The structures can be pretreated to ensure lower annealing temperature bonding.

FIG. 3C depicts a cross-sectional view of a further intermediate structure 121 resulting from the flipping of the wafer structure 131 of FIG. 3B and the removing of the bottom Si substrate layer 102. The substrate 102 of the intermediate structure of FIG. 3B can be removed using reactive ion etch (RIE) or chemical-mechanical polishing (CMP) techniques.

FIG. 3D depicts a cross-sectional view of a further intermediate structure 131 resulting from further removal of the etch stop layer 105 and the further Si-epi material layer 108. The Si epi layer 108 and etch stop layers 105 can be removed using RIE or other mechanical-chemical etching techniques. In the flipped wafer, the etching/removal of the Si-epi layer 108 exposes a backside surface 135. Further, as a result of the etching/removal of the Si-epi layer 108, there remain openings 138 in STI layer 128 between the STI structures 113 where the openings expose a source terminal/region or drain terminal/region of a transistor forming a respective SRAM memory device 115.

FIG. 3E depicts a cross-sectional view of a further intermediate structure 141 resulting from an additional step of building a backside interlevel dielectric material layer 148 above the backside surface 135, the layer of STI structures 113 and DRAM device layer 110. That is, while the wafer is still flipped, there is deposited on the STI layer an interlevel dielectric material, e.g., which can be the same dielectric material as the ILD level 130, e.g., deposited using include a thermal and/or plasma assisted chemical vapor deposition (CVD) technique. The deposited backside ILD material layer 148 fills the formed openings 138 beneath the source terminal/region or drain terminal/region of a transistor forming a respective SRAM memory device 115.

FIG. 3F depicts a cross-sectional view of a further intermediate structure 151 resulting from an additional step of forming conductive backside contact structures 153 that replace the ILD material deposited in the respective STI layer openings 138 and formed to contact a respective source terminal/region or drain terminal/region of a transistor forming a respective SRAM memory device 115. That is, while the wafer is still flipped, using photolithographic semiconductor manufacturing techniques, a resist may be patterned to provide openings in the ILD layer 148 aligned to corresponding formed openings 138 in the STI layer and then a successive RIE etch step(s) are employed to form the openings beneath a respective source terminal/region or drain terminal/region of a transistor forming a respective SRAM memory device 115. Then, a subsequent metal material deposition technique, e.g., ALD, CVD, PECVD, PVD, plating or sputtering, etc. is applied to form the individual conductive backside contacts 153 in the openings that electrically connect with source terminal/region or drain terminal/region of a transistor forming a respective SRAM memory device 115. The backside contact conductor material can include a conductive metal, such as W, Cu, Al, Co, Ru, Mo, Os, Ir, Rh or an alloy thereof. Further photolithographic semiconductor manufacturing techniques can be applied to form further backside power rail pads that connect to one or more backside contacts 153. A backside power rail pad, e.g., metal or metal-alloy material pads 155 is dedicated for a ground terminal (e.g., V_{SS}) connection and a metal or metal-alloy material pads 157 is dedicated for a power source, e.g., a power rail voltage terminal (e.g., V_{DD}) connection. These backside power rail voltage pads 155 (VSS) and backside power rail voltage pads 157 (VDD) electrically connect to SRAM device 115 via backside contacts 153. Further, deposited on each of the backside power rail pads 155, 157 is a respective cap dielectric material layer 165, 167 respectively. Further, as shown in the further intermediate structure 151 of FIG. 3F is the formation of a similar conductive contacts 153 connecting to a respective global via connection 125, 126, and these contacts can further connect to backside power rail pads 155 (VSS) and backside power rail pads 157 (VDD) for electrical connection thereof. These backside power rails 155 (e.g., VSS) and backside power rails 157 (e.g., VDD) further include a respective cap dielectric material layer 165, 167 formed on top of the pad. As shown, the resulting structure 151 of FIG. 3F includes a planarized backside surface 145, e.g., as a result of a further chemical-mechanical polishing (CMP) step(s). In an embodiment, the power rails which can be formed in contact with the backside bottom S/D contact structure of an SRAM Device 115 can include any electrically conductive power rail material including, but not limited to, tungsten (W), cobalt (Co), ruthenium (Ru), aluminum (Al), copper (Cu), platinum (Pt), rhodium (Rh), or palladium (Pd).

FIG. 3G depicts a cross-sectional view of a further intermediate structure 161 resulting from an additional step of forming much larger conductive backside contacts pad (power rail) structures 170 that connect a respective power rail, e.g., backside power rails 155, to increase the size of the power rail pad to ground (e.g., V_{SS}). A similar structure not shown in FIG. 3G is formed to connect respective power rails 157 to increase the size of the power rail pad for power rail voltage (e.g., V_{DD}). In an embodiment, the larger backside power supply pad 170 is formed with abrupt increase in metal pitch and size, by selectively opening a type of dielectric cap, e.g., removing dielectric caps 165 for connectors 153 that connect with corresponding VSS power rails 155 and then forming the VSS contact structure pad structure 170 to connect with the smaller VSS backside power rail pads 155. Adjacent conductive pads 157 that are formed to carry the other power rail voltage are separated and electrically isolated from the larger VSS pad 170 by the presence of cap dielectric layer 167, i.e., the dielectric caps 167 that connect with VDD power rail pads 157 at adjacent connectors 153 are not removed. However, similarly, there is performed selectively opening a type of dielectric cap, e.g., removing dielectric caps 167 for connectors 153 that connect with corresponding VDD power rails 157 and then forming a much larger VDD contact structure pad (not shown), to connect with the smaller VDD backside power rail pads 157. In an embodiment, the larger VSS backside power rail pad 170 and similarly larger VDD backside power rail pad (not shown) are large enough for subsequent hybrid bonding step. In an embodiment, as shown in FIG. 3G, an additional via connection 168 is formed that can connect a backside VSS power rail contact 170 to the global via connection 125 for global power communication. Although not shown, a similar via connection is formed that can connect a backside VDD power rail contact to the global via connection 126 for global power communication somewhere into the plane of the page. As shown, the resulting structure 161 of FIG. 3G includes a planarized backside surface 175, e.g., as a result of a further chemical-mechanical polishing (CMP) step(s).

FIG. 3H depicts an identical resulting structure 261 as structure 161 however formed on a second wafer 45 using the identical method steps as depicted in FIGS. 3A-3G. This second wafer structure 45 showing structure 261 includes the SRAM memory device layout 210 having SRAM devices 215 formed above an STI layer 228 having STI structure 213 isolating the epitaxially grown source drain terminals (S/D epi) of SRAM devices 215 and having formed one or more interlevel dielectric material layers 220 above that include a distribution of conductors 217, 219 at various metallization levels. As in the first SRAM device wafer 40, there is included various via structures 218 that connect a conductor 217 to an SRAM device S/D epi terminal or connect conductors 217 or a via 222 that connect conductors 217 at different metallization levels. Bonded to a top surface 232 of the one or more interlevel dielectric material layers 220 is a carrier wafer 203. Further formed in and extending through interlevel dielectric material layers 220 are global communication vias 225, 226. Once the wafer is flipped, further fabrication steps enabling forming of a backside interlevel dielectric material layer 248 atop the STI layer 228 and forming of a series of metal contact structures 253 that electrically connect STI-isolated epitaxially grown source drain terminals (S/D epi) of SRAM devices 215 to underlying conductive pads, such as conductive VSS power rail pads 255 and to conductive VDD power rail pads 257 of the backside power delivery network. Further, as shown in the structure 261 of FIG. 3H is the formation of a similar conductive contacts 253 that connect a respective global via connection 225, 226, to backside power rail pads 255 (VSS) and backside power rail pads 257 (VDD) for electrical connection thereof.

As shown in FIG. 3H, the backside power delivery network further includes a formed larger backside power supply pad 270, e.g., for a ground (or VSS power rail) connection, that electrically connect to multiple smaller VSS connectors 255 having cap dielectric material removed. Adjacent VDD conductive pads 257 that carry the other power rail voltage are separated and electrically isolated from the larger VSS pad 270 by the presence of cap dielectrics 267 formed on the connector 257. Similarly, although not shown, there is formed a larger backside power supply pad for carrying a VDD backside power voltage rail that connect to multiple smaller VDD connectors 257 having its overlying cap dielectric layer 267 removed. In this embodiment, adjacent dielectric caps overlying a VSS power rail pad at adjacent connectors are not removed, i.e., they are separated and electrically isolated from the larger VDD pad (not shown) by the presence of cap dielectrics. As shown in structure 261, each larger VDD pad (not shown) and corresponding connected smaller VDD connector pad 257 and similarly each larger VSS pad 270 and corresponding connected smaller VSS connector pad 255 connect to an epitaxially grown source drain terminals (S/D epi) of SRAM devices 215 in SRAM Device layer 210. In an embodiment, the larger VSS backside power rail pad 270 and similarly larger VDD backside power rail pad (not shown) are large enough for subsequent hybrid bonding step. In an embodiment, as shown in FIG. 3H, an additional via connection 268 is formed that can connect a backside conductive VSS power rail voltage pad 270 to the global via connection 225 for global power communication. Although not shown, a similar via connection is formed that can connect a backside VDD power rail voltage contact to the global via connection 226 for global power communication somewhere into the plane of the page. As shown, the resulting structure 261 of FIG. 3H includes a planarized backside surface 275, e.g., as a result of a further chemical-mechanical polishing (CMP) step(s).

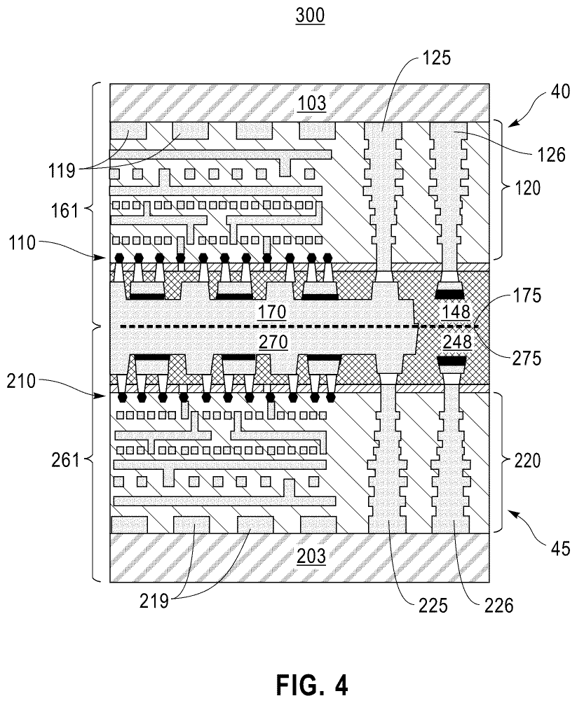

FIG. 4 depicts a resulting two-layer (2-layer) SRAM die structure 300 formed by hybrid bonding of two SRAM dies 40, 45 including the bonding of the surface 175 of single die 40 of FIG. 3G having respective backside power delivery network circuitry connecting first SRAM device layout 110 to the surface 275 of a flipped single die 45 of FIG. 3H having respective backside power delivery network circuitry connecting second SRAM device layout 210. That is, as shown in FIG. 4, the larger formed power rail conductor pad 170 of first wafer having first SRAM device layout 110 is bonded to the larger formed power rail conductor pad 270 of second wafer having second SRAM device layout 210. The interlevel dielectric material layers 148, 248 are also bonded together using the known hybrid bonding technique. Thus, the resulting structure 300 shown in FIG. 4 is a bonded 3-D vertical stack of two SRAM device wafers, each wafer having a respective SRAM memory device layout, oriented in parallel to each other, and SRAM memory devices having a common power source in the form of bonded larger power rail voltage pads 170, 270 from the respective wafers. The hybrid bonded 3-D vertical stack of two SRAM device wafers includes a top carrier wafer substrate 103 at a top surface and a bottom carrier wafer substrate 203 at a bottom surface.

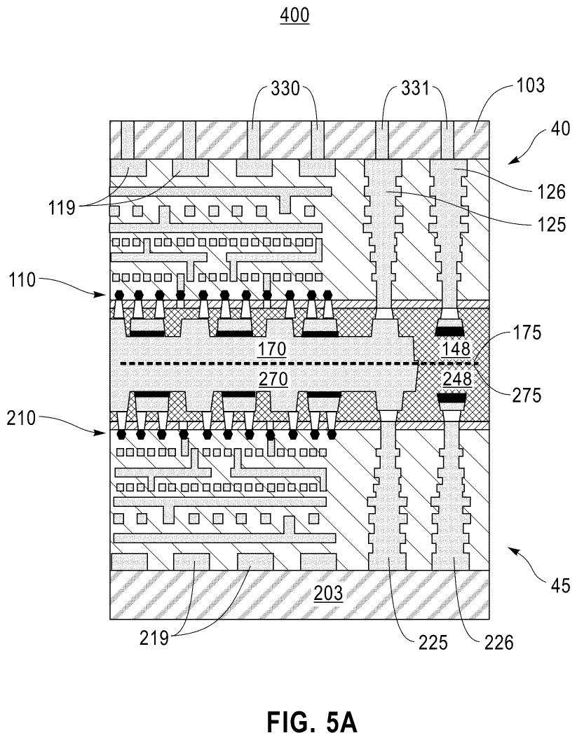

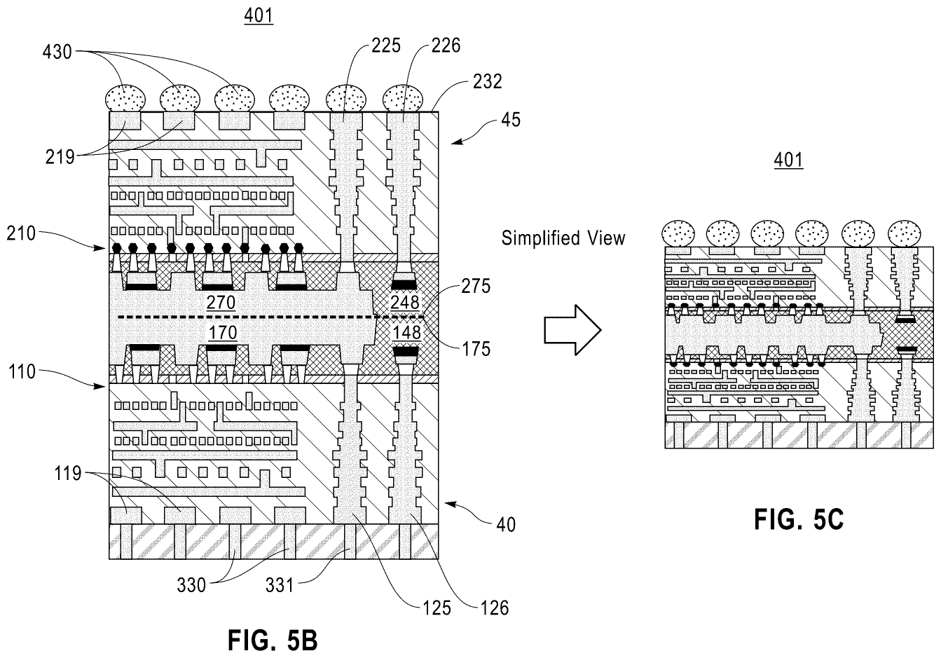

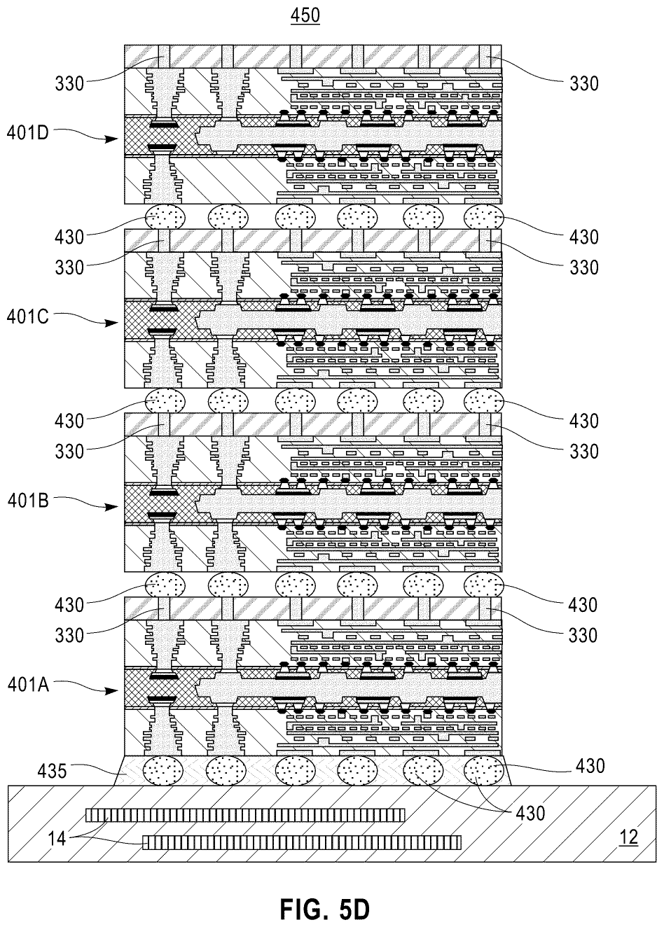

FIGS. 5A-5C depict further performed method steps for increasing the size of the vertical stack of SRAM device wafers and amount of SRAM according to a first embodiment. In particular, FIG. 5A depicts a resulting 2-layer SRAM die structure 400 after performing CMP or grinding steps to thin down the top carrier wafer 103 and after the photolithographic semiconductor patterning, etching and metal material deposition steps to form through silicon via structures (TSVs) 330 through the top wafer. That is, as shown in the structure 400, a respective TSV structure 330 is formed to extend from a metallization level conductor, e.g., conductor 119, to the surface of the top wafer 103. Similarly, a respective TSV structure 331 is formed to extend from a global communications via 125, 126 to the surface of the top wafer 103.

FIG. 5B depicts a resulting 2-layer SRAM structure 401 after flipping the bonded wafers 40, 45 having respective SRAM device layers 110, 210 and removing the top carrier wafer 203 from the structure 400 of FIG. 5A to expose top surface 232. FIG. 5B further depicts the resulting structure 401 after performing photolithographic semiconductor patterning, etching and metal material deposition steps to form C4 or like solder bumps 430 that are aligned and electrically connect at the top surface 232 with a respective metallization wire or conductor 219 and also aligned with and electrically connect with an exposed surface of the global communication vias 225, 226. FIG. 5C shows a simplified view of the two-layer SRAM die stacked structure 401 of FIG. 5B, i.e., a formed 2-layer SRAM die 401.

FIG. 5D shows a resulting final bonded 3-D vertical stacked structure 450 of multiple 2-layer SRAM dies shown in FIG. 5C formed on a laminate substrate or interposer or like carrier substrate 12. In particular, the 3-D vertical stack 450 includes multiple (e.g., “n”, where n>0) 2-layer SRAM die structures 401 of FIG. 5C connected on top of each other via hybrid bonded connections. As shown in FIG. 5D, in an illustrative, non-limiting embodiment, when n=4, the vertically stacked SRAM wafter structure 450 from bottom to top includes electrically connected two-layer SRAM dies (stacked structures) 401A, 401B, 401C, 401D shown in FIG. 5C that are aligned and connect with each other using C4 bump interconnects. While four layers 401A-401D of stacked SRAM structures are shown, more layers, e.g., when n=8, four additional 2-layer SRAM dies, can be vertically stacked to increase the size and amount of SRAM devices. In embodiments, “n” can be greater or equal to 8. In the stacked 3-D SRAM wafer structure, a first two-layer SRAM dies 401A includes bottom C4 or solder bumps 430 that are subject to bonding techniques to connect to aligned conductors exposed at a surface of the laminate or interposer carrier 12. Via other conductors (not shown) the bottom C4 or solder bumps 430 connector can electrically connect with conductors or other wire structures 14 formed in the laminate or interposer carrier 12. A second two SRAM wafer stacked structure 401B includes C4 or solder bumps 430 that electrically connect to exposed TSV structures 330 at a top surface of the underlying first two SRAM wafer stacked structure 401A of stack 450. Similarly, a third two SRAM wafer stacked structure 401C includes C4 or solder bumps 430 that electrically connect to exposed TSV structures 330 at a top surface of the underlying second two SRAM wafer stacked structure 401B of stack 450. Finally, in the illustrative embodiment, a fourth two SRAM wafer stacked structure 401D includes C4 or solder bumps 430 that electrically connect to exposed TSV structures 330 at a top surface of the underlying third two SRAM wafer stacked structure 401C of stack 450. It is understood that further SRAM wafer stacks may be added on top the fourth two SRAM wafer stacked SRAM structure 401D that will connect to exposed TSV structures 330 at the top level structure 401D. In FIG. 5D, the resulting structure is mechanically reinforced and stabilized with provision of an underfill material layer 435 encompassing the C4 or solder bumps 430 at the top surface of the laminate or interposer.

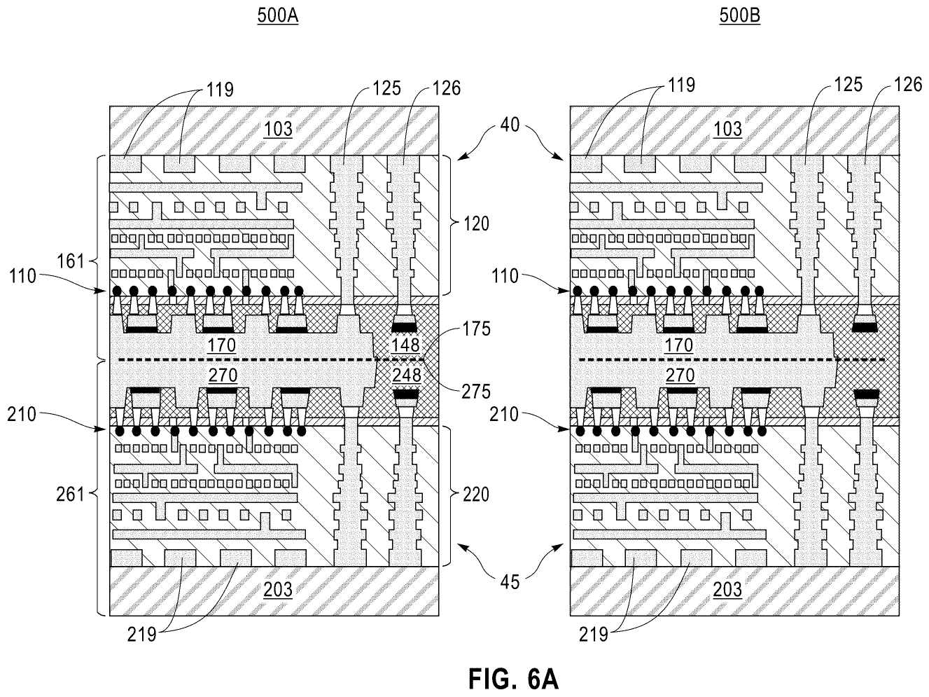

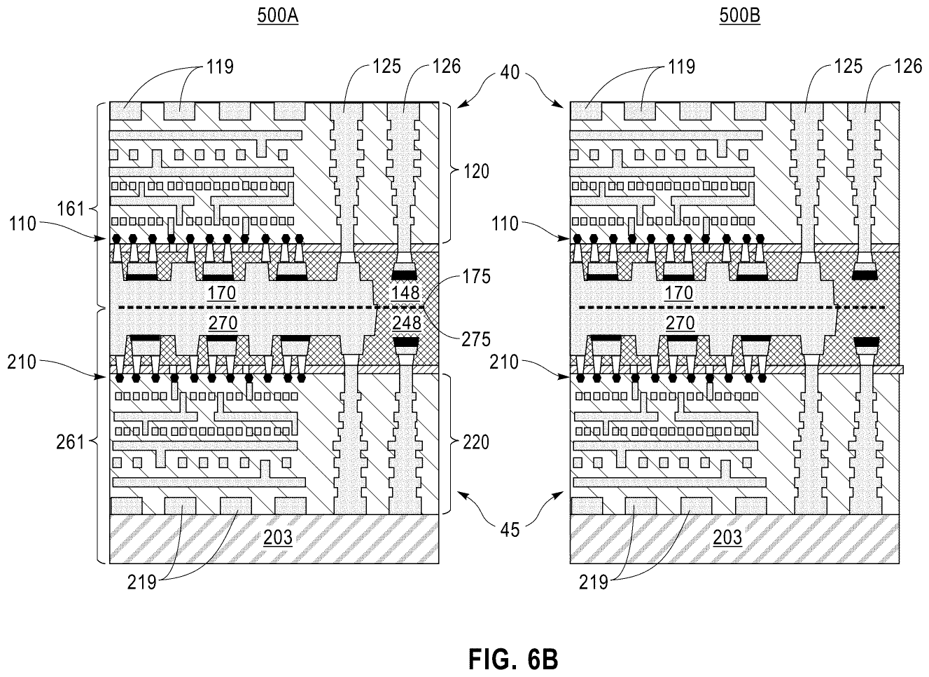

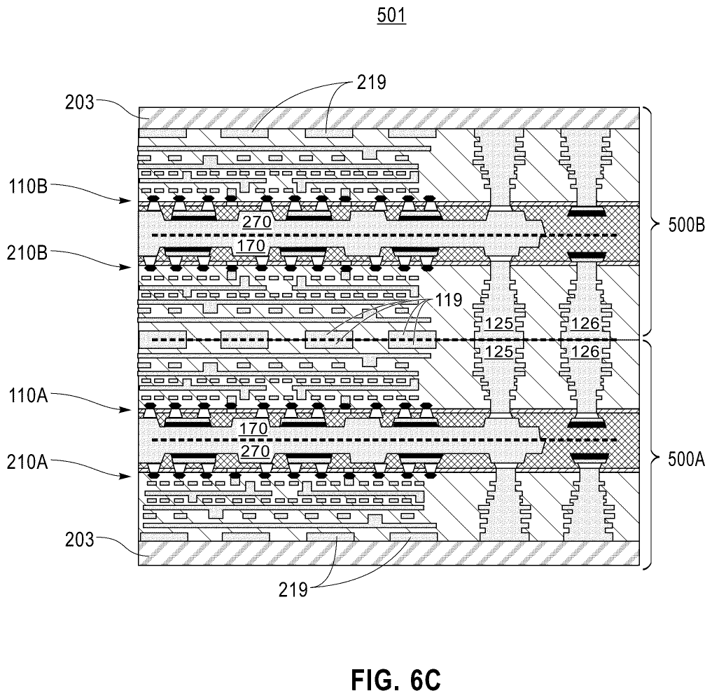

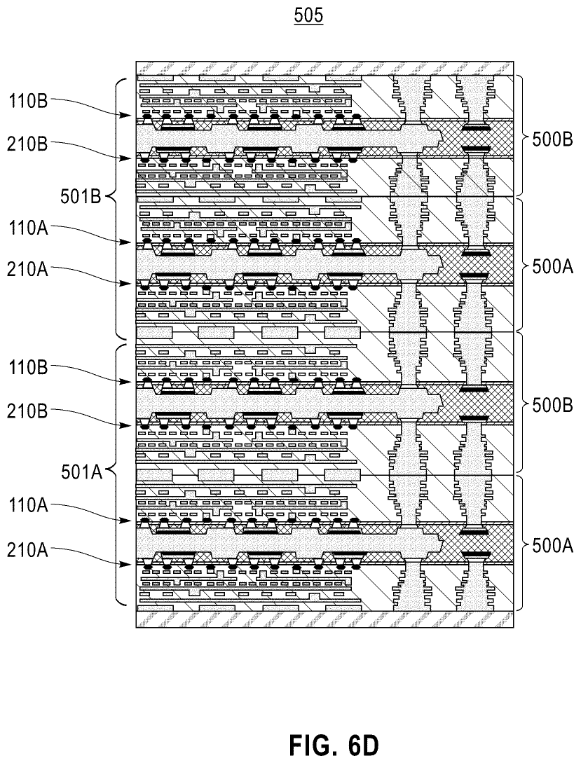

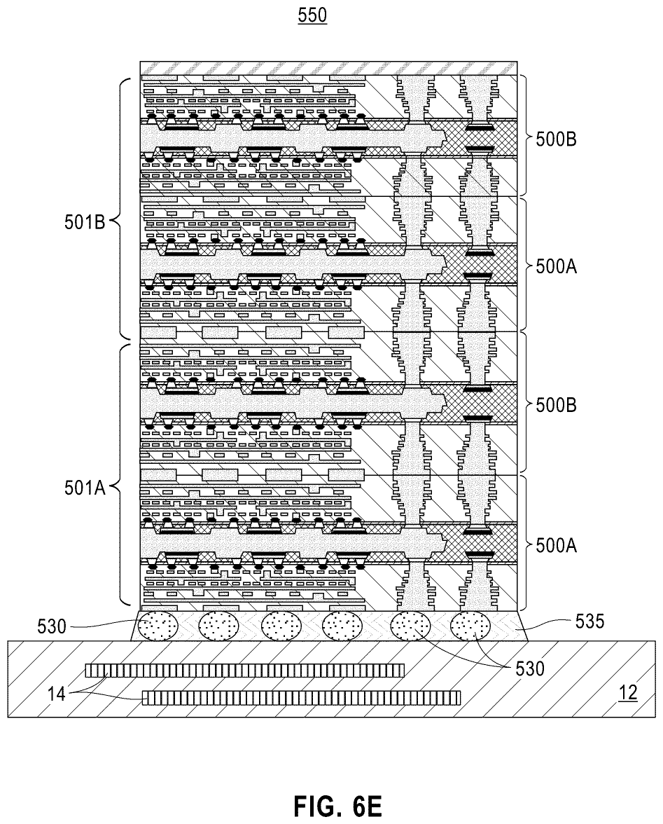

FIGS. 6A-6C depict a further embodiment for stacking SRAM wafers to form a bonded 4-layer SRAM dies as a vertical stacked SRAM structure. As shown in FIG. 6A, there is depicted a result of first forming two 2-layer SRAM die structures 500A, 500B, each structure 500A, 500B structurally identical to the hybrid bonded two-layer SRAM die structure 300 of FIG. 4. Continuing to FIG. 6B there is depicted a result of removing the top carrier wafer 103 at the surface of each prepared 2-layer SRAM die structure 500A, 500B. FIG. 6C depicts a stacked SRAM structure 501 resulting from a subsequent front-front hybrid bonding of the individual prepared structures 500A, 500B of FIG. 6B. In the resulting structure 501 of FIG. 6C, the hybrid bonding includes the aligning of the top surface wire conductors 119 and the aligning of the global communications vias 125, 126 of each respective two-layer SRAM stack wafer structure 500A, 500B and the hybrid bonding to form a stacked four-layer SRAM die structure, i.e., a 4-layer SRAM die 501 having four SRAM device layers 110A, 210A of first 2-layer SRAM die structure 500A and SRAM device layers 110B, 210B of second 2-layer SRAM die structure 500B. This sequence of hybrid bonding of each two-layer SRAM die stack structure is repeated and resulting hybrid bonded structures consisting of a stack of hybrid bonded 2-layer SRAM die structures 500A, 500B can be further stacked on top each other and bonded to form a 4-layer SRAM die or 8-layer SRAM die. For instance, as shown in FIG. 6D, there is depicted a formed “n” layer, e.g., where n=8, to result in an 8-layer SRAM die structure 505. The 8-layer SRAM die structure 505 results by hybrid bonding of a bottom 4-layer SRAM die structure 501A corresponding to the hybrid bonded structure 501 of FIG. 6C that is a hybrid bonded stack including a two hybrid bonded 2-layer SRAM die structures 500A, 500B to a top 4-layer SRAM die structure 501B corresponding to the hybrid bonded structure 501 of FIG. 6C that is a hybrid bonded stack including two hybrid bonded 2-layer SRAM die structures 500A, 500B. In the final hybrid bonded SRAM die structure 505 of FIG. 6D, there are provided a total of eight SRAM device levels 110A, 210A. It is understood that further 2-layer SRAM dies 500A or 4-layer SRAM dies 501 may be added (i.e., hybrid bonded) to the topmost four-layer SRAM die stacked SRAM structure 501B of FIG. 6D.

FIG. 6E shows a resulting final bonded 3-D vertical stack structure 550 of a formed 8-layer SRAM die structure 550 (stack of SRAM device wafers) shown in FIG. 6D formed on and electrically connected to laminate substrate or interposer or like carrier substrate 12. In particular, the 3-D vertical stack 550 includes the two four SRAM wafer stack structures 501A, 501B of FIG. 6D connected on top of each other. As shown in FIG. 6E, in an illustrative, non-limiting embodiment, the vertically stacked SRAM wafter structure 550 from bottom to top includes electrically connected four SRAM wafer stacked structures 501A, 501B, shown in FIG. 6D that are aligned and connect with each other. While four layers 500A, 500B of stacked SRAM structures are shown, additional layers can be stacked to increase the size and amount of SRAM devices. In the stacked 3-D SRAM wafer structure 550, a first four wafer SRAM wafer stacked structure 501A includes bottom C4 or solder bumps 530 that connect to aligned conductors exposed at a surface of the laminate or interposer carrier 12. Via other conductors (not shown) the bottom C4 or solder bumps 430 connector can electrically connect with conductors or other wire structures 14 formed in the laminate or interposer carrier 12. In FIG. 6E, the resulting structure is mechanically reinforced and stabilized with provision of an underfill material layer 535 encompassing the C4 or solder bumps 530 at the top surface of the laminate or interposer.

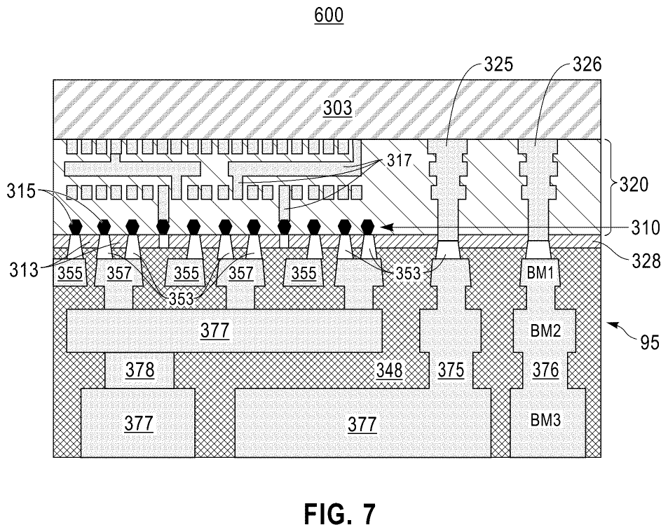

FIG. 7 depicts an embodiment of a single layer SRAM die 600 that includes three metal layers (levels) on both frontside and backside of the die in an embodiment. That as shown in FIG. 7, formed on a single wafer or die 95 using the method steps as depicted in FIGS. 3A-3G, are the SRAM memory device layout 310 having SRAM devices 315 formed above an STI layer 328 having STI structures 313 isolating the epitaxially grown source drain terminals (S/D epi) of SRAM devices 315 and having formed one or more interlevel dielectric material layers 320 above that includes a distribution of conductors at various metallization levels, e.g., at least three metallization levels M1, M2, M3. As in other embodiments herein, SRAM device wafer 95 includes formed via structures that connect a metal conductor 317 in an interlevel dielectric layer to an SRAM device S/D epi terminal or a via that connect conductors 317 at different metallization levels. Bonded to a top surface of the one or more interlevel dielectric material layers 320 is a carrier wafer 303. Further formed in and extending through interlevel dielectric material layers 320 are global communication vias 325, 326. Once the wafer is flipped, further fabrication steps enabling forming of a backside interlevel dielectric material layer 348 atop the STI layer 328 and the forming of a series of backside metal contact structures 353 that electrically connect STI-isolated epitaxially grown source/drain terminals (S/D epi) of SRAM devices 215 to underlying conductive structures. In an embodiment, underlying conductive structures connected to SRAM device source/drain epi terminals include underlying conductive pads, such as conductive VSS power rail (e.g., ground) pads 355 and conductive VDD power rail voltage pads 357 of a backside power delivery network. In the embodiments of FIG. 7, further via connections can connect conductive VSS power rail (e.g., ground) pads 355 and conductive VDD power rail voltage pads 357 to further conductors 377, e.g., wires, traces formed in any of three backside metallization levels BM1, BM2, BM3 in backside interlevel dielectric layers 348. As further shown in FIG. 7, further conductors 377 can connect to other conductor structures 377 at different metallization levels using formed via connectors 378 formed in backside interlevel dielectric 348 Further, as shown in structure 600 of FIG. 7 is the formation of similar conductive contacts 353 that connect a respective global via connections 325, 326, to aligned corresponding backside global communication vias 375, 376 for electrical connection thereof. The single layer SRAM die structure 600 in FIG. 7 shows SRAM 310 layer with three (3) metal layers both frontside and backside.

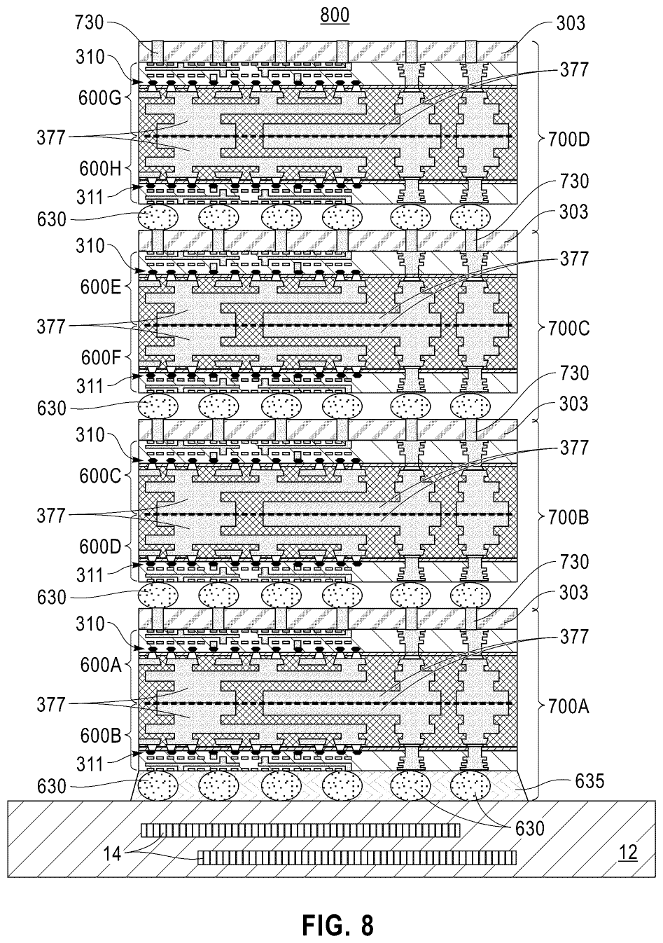

As shown in the cross-sectional view of FIG. 8, there is provided a further 3D-stacked SRAM device structure 800 according to a further embodiment. Using the similar methods as shown in FIGS. 6A-6D, there is first prepared several 2-layer SRAM dies 700A, 700B, 700C, 700D each consisting of two single layer SRAM die structures 600 of FIG. 7 that are hybrid bonded together. Particularly, the methods form a 2-layer SRAM die 700A consisting of the two bonded single layer SRAM die structures 600A, 600B (identical to structure 600 of FIG. 7) that are hybrid bonded together, with each single layer SRAM die structure 600A, 600B having three BEOL interconnects, e.g., frontside metal layers M1, M2, M3 and three backside metal layers BM1, BM2, BM3. In the hybrid bonded 2-layer SRAM die structure 700A, the backside metallization layer wires or conductors 377 of the single layer SRAM die structure 600A align with and are bonded to corresponding bottom layer wires or conductors 377 of the flipped single layer SRAM die structure 600B. Formed within carrier wafer 303 of the single layer SRAM die structure 600A are TSV structures 730 that align with and can electrically connect to wires or conductors formed in the frontside metallization level 320 of FIG. 7. Additionally, formed above the frontside metallization level 320 of the flipped single layer SRAM die structure 600B are C4 or solder bumps structures 630 that align with and electrically connect to wires or conductors formed in the frontside metallization level 320 of FIG. 7. The formed 2-layer SRAM die 700A consisting of the two bonded single layer SRAM die structures 600 of FIG. 7 include frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377.

The 3-D stacked SRAM structure 800 of FIG. 8 includes a further 2-layer SRAM die 700B consisting of two single layer SRAM die structures 600 of FIG. 7 that are hybrid bonded together and connected to a top surface of underlying 2-layer SRAM die 700A. Particularly, using the similar methods of FIGS. 6A-6C there is first formed a 2-layer SRAM die 700B consisting of a single layer SRAM die structure 600C and a flipped single layer SRAM die structure 600D that are hybrid bonded together. In the stack 800, C4 or solder bump structures 630 formed at the top surface of the flipped single layer SRAM die 600D electrically connect with and are bonded to exposed top surfaces of TSVs 730 formed in the carrier wafer 303 of the underlying first 2-layer SRAM die 700A. Each single layer SRAM die structure 600C and flipped single layer SRAM die structure 600D have three frontside metal layers M1, M2, M3 and three backside metal layers BM1, BM2, BM3 and also include frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377.

The 3-D stacked SRAM structure 800 of FIG. 8 includes a further 2-layer SRAM die 700C consisting of two single layer SRAM die structures 600 of FIG. 7 that are hybrid bonded together and connected to a top surface of underlying 2-layer SRAM die 700B. Particularly, using the similar methods of FIGS. 6A-6C there is first formed a 2-layer SRAM die 700C consisting of a single layer SRAM die structure 600E and a flipped single layer SRAM die structure 600F that are hybrid bonded together. In the stack 800, C4 or solder bump structures 630 formed at the top surface of the flipped single layer SRAM die 600F electrically connect with and are bonded to exposed top surfaces of TSVs 730 formed in the carrier wafer 303 of the underlying 2-layer SRAM die 700B. Each single layer SRAM die structure 600E and flipped single layer SRAM die structure 600F have three frontside metal layers M1, M2, M3 and three backside metal layers BM1, BM2, BM3 and also include frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377.

The 3-D stacked SRAM structure 800 of FIG. 8 includes a further 2-layer SRAM die 700D consisting of two single layer SRAM die structures 600 of FIG. 7 that are hybrid bonded together and connected to a top surface of underlying 2-layer SRAM die 700C. Particularly, using the similar methods of FIGS. 6A-6C there is additionally formed the 2-layer SRAM die 700D consisting of a single layer SRAM die structure 600G and a flipped single layer SRAM die structure 600H that are hybrid bonded together. In the stack 800, C4 or solder bump structures 630 formed at the top surface of the flipped single layer SRAM die 600H electrically connect with and are bonded to exposed top surfaces of TSVs 730 formed in the carrier wafer 303 of the underlying 2-layer SRAM die 700C. Each single layer SRAM die structure 600G and flipped single layer SRAM die structure 600H have three frontside metal layers M1, M2, M3 and three backside metal layers BM1, BM2, BM3 and also include frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377. The top single SRAM memory die 600G can include carrier wafer 303 with additional TSV connectors 730 for stacking further SRAM memory structures on top of the 3-D stacked SRAM memory structure 800 shown in FIG. 8.

Further, as shown in FIG. 8, the flipped single SRAM die 600B of the first 2-layer SRAM die 700A of the stacked 3-D SRAM memory structure 800 includes bottom C4 or solder bumps 630 that connect to aligned conductors exposed at a surface of a laminate or interposer carrier 12. Via other conductors (not shown) the bottom C4 or solder bumps 630 connector can electrically connect with conductors or other wire structures 14 formed in the laminate or interposer carrier 12. In FIG. 8, the resulting structure is mechanically reinforced and stabilized with provision of an underfill material layer 635 encompassing the C4 or solder bumps 630 at the top surface of the laminate or interposer.

Further, it is understood that the stacked 3-D SRAM structure 800 of FIG. 8, is not limited to four 2-layer SRAM dies 700A-700D that provide eight (8) SRAM memory layers 310, 311. Additional SRAM hybrid bonded devices can be connected to the stack to provide twelve (12) or more SRAM memory devices layers 310, 311.

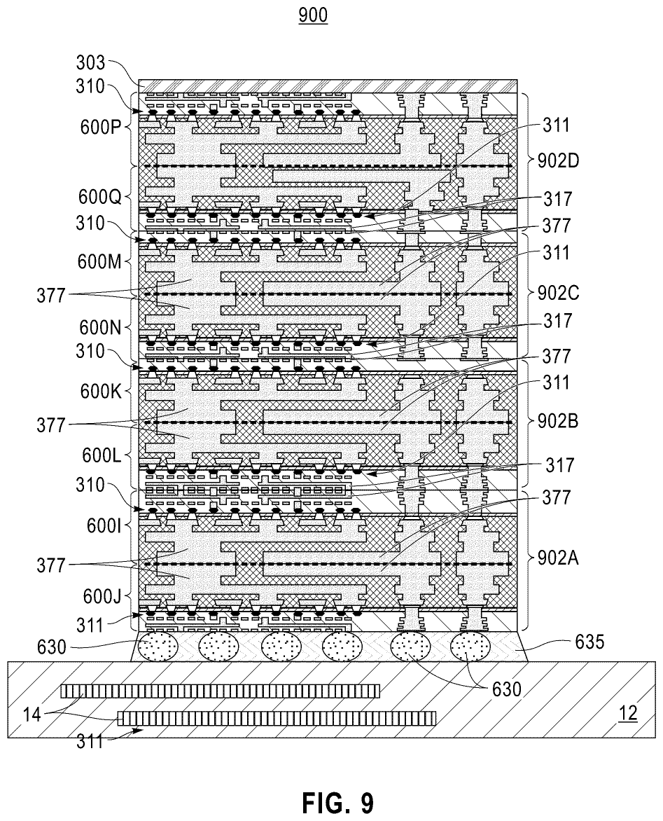

As shown in the cross-sectional view of FIG. 9, there is provided a further 3D-stacked SRAM device structure 900 according to a further embodiment. Using the similar methods as shown in FIGS. 6A-6D, there is first prepared several 2-layer SRAM dies 902A, 902B, 902C, 902D each consisting of two single layer SRAM die structures 600 of FIG. 7 that are hybrid bonded together. Particularly, the first form a 2-layer SRAM die 902A consisting of the two bonded single layer SRAM die structures 600I, 600J (identical to structure 600 of FIG. 7) that are hybrid bonded together, with each single layer SRAM die structures 600I, 600J having three frontside metal layers M1, M2, M3 and three backside metal layers BM1, BM2, BM3. In the hybrid bonded 2-layer SRAM die structure 902A, the backside metallization layer wires or conductors 377 of the single layer SRAM die structure 600I align with and are electrically connected and bonded to corresponding backside metallization layer wires or conductors 377 of the flipped single layer SRAM die structure 600J. In an embodiment depicted in FIG. 9, the frontside metallization level conductors 317 of a formed hybrid bonded 2-layer SRAM die structure, e.g., 902A, can connect to formed frontside metallization level conductors 317 of an adjacent flipped 2-layer SRAM die 902B. The formed 2-layer SRAM die 902A further consists of frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377. In the embodiment of FIG. 9, the 2-layer SRAM die 902A is a bottom most structure of the stacked 3-D SRAM memory structure 900 and the flipped single SRAM die 600J includes bottom C4 or solder bumps 630 that connect to aligned conductors exposed at a surface of a laminate or interposer carrier 12. Via other conductors (not shown) the bottom C4 or solder bumps 630 connector can electrically connect with conductors or other wire structures 14 formed in the laminate or interposer carrier 12. Thus, in this embodiment, the formed hybrid bonded 2-layer SRAM die structure 902A does not include a carrier wafer but does connect to the interposer or laminate using C4 bumps 630 or similar conductive structures aligned with corresponding conductors. In FIG. 9, the resulting structure is mechanically reinforced and stabilized with the provision of an underfill material layer 635 encompassing the C4 or solder bumps 630 at the top surface of the laminate or interposer.

The 3-D stacked SRAM structure 900 of FIG. 9 includes a similarly constructed further 2-layer SRAM die 902B connected to a top surface of underlying 2-layer SRAM die 902A. Particularly, using the similar methods of FIGS. 6A-6D there is further formed a 2-layer SRAM die 902B consisting of a single layer SRAM die structure 600K and a flipped single layer SRAM die structure 600L that are hybrid bonded together. In the hybrid bonded 2-layer SRAM die structure 902B, the backside metallization layer wires or conductors 377 of the single layer SRAM die structure 600K align with and are electrically connected and bonded to corresponding backside metallization layer wires or conductors 377 of the flipped single layer SRAM die structure 600L. In the stack 900, frontside metallization level conductors 317 formed at the top surface of the single layer SRAM die 600I of 2-layer SRAM die 902A electrically connect with and are bonded to corresponding frontside metallization level conductors 317 formed on the flipped single layer SRAM structure 600L of the overlying 2-layer SRAM die 902B. In embodiments, each single layer SRAM die structure 600K and flipped single layer SRAM die structure 600L have three frontside metal layers M1, M2, M3 and three backside metal layers BM1, BM2, BM3 and also include frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377. The formed hybrid bonded 2-layer SRAM die structure 902B does not include a carrier wafer with TSVs nor C4 bumps for physical and electrical connection.

The 3-D stacked SRAM structure 900 of FIG. 9 includes a further constructed 2-layer SRAM die 902C consisting of two single layer SRAM die structures 600 of FIG. 7 that are hybrid bonded together and connected to a top surface of underlying 2-layer SRAM die 902B. Particularly, using the similar methods of FIGS. 6A-6C there is first formed a 2-layer SRAM die 902C consisting of a single layer SRAM die structure 600M and a flipped single layer SRAM die structure 600N that are hybrid bonded together. In the hybrid bonded 2-layer SRAM die structure 902C, the backside metallization layer wires or conductors 377 of the single layer SRAM die structure 600M align with and are electrically connected and bonded to corresponding backside metallization layer wires or conductors 377 of the flipped single layer SRAM die structure 600N. In the stack 900, frontside metallization level conductors 317 formed at the top surface of the single layer SRAM die 600K of 2-layer SRAM die 902B can electrically connect with and are bonded to corresponding frontside metallization level conductors 317 formed on the flipped single layer SRAM structure 600N of the adjacent overlying 2-layer SRAM die 902C. In embodiments, each single layer SRAM die structure 600M and flipped single layer SRAM die structure 600N have three frontside metal layers M1, M2, M3 and three backside metal layers BM1, BM2, BM3 and also include frontside SRAM memory device layout 310 and backside SRAM memory device layout 311. The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377. The formed hybrid bonded 2-layer SRAM die structure 902B does not include a carrier wafer with TSVs nor C4 bumps for physical and electrical connection.

The 3-D stacked SRAM structure 900 of FIG. 9 includes a further 2-layer SRAM die 902D consisting of two single-layer SRAM die structures 600 of FIG. 7 that are hybrid bonded together and connected to a top surface of underlying 2-layer SRAM die 902C. Particularly, using the similar methods of FIGS. 6A-6C is formed a 2-layer SRAM die 902D consisting of a single-layer SRAM die structure 600P and a flipped single-layer SRAM die structure 600Q that are hybrid bonded together. In the hybrid bonded 2-layer SRAM die structure 902D, the backside metallization layer wires or conductors 377 of the single-layer SRAM die structure 600P align with and are electrically connected and bonded to corresponding backside metallization layer wires or conductors 377 of the flipped single layer SRAM die structure 600Q. In the stack 900, frontside metallization level conductors 317 formed at the top surface of the single layer SRAM die 600M of 2-layer SRAM die 902C electrically connect with and are bonded to corresponding frontside metallization level conductors 317 formed on the flipped single layer SRAM structure 600Q of the adjacent overlying 2-layer SRAM die 902D. In embodiments, each single layer SRAM die structure 600P and flipped single layer SRAM die structure 600Q have three frontside metal layers M1, M2, M3 and three backside metal layers BM1, BM2, BM3 and also include frontside SRAM memory device layout 310 and backside SRAM memory device layout 311.

The SRAM devices of both frontside SRAM memory device layout 310 and of backside SRAM memory device layout 311 further include metal contacts that electrically connect to conductive pads or like structures 355 that provide power signals, e.g., ground or VSS voltage level, and like conductive pads or structures 357 that provide power signals, e.g., rail voltages VDD to the SRAM devices and which can connect to other conductors or wires 377. The topmost 2-layer SRAM die 902D can include a carrier wafer 303 at the top surface thereof.

It is understood that the stacked 3-D SRAM structure 900 of FIG. 9, is not limited to four 2-layer SRAM dies 902A-902D that provide eight (8) SRAM memory layers 310, 311. Additional SRAM hybrid bonded devices can be connected to the stack to provide twelve (12) or more SRAM memory devices layers 310, 311.

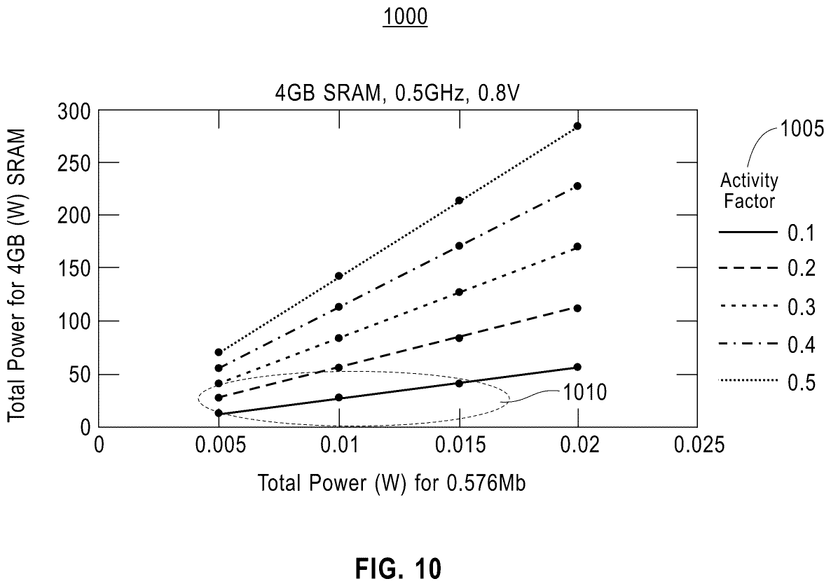

FIG. 10 shows a graph 1000 depicting a power consumption for a 4 GB SRAM (in Watts) plotted against a lesser cache memory hardware and is based on example 5 nm SRAM L2 Cache hardware measurements at different activity factors 1005. As shown in FIG. 10, a low power SRAM can be generated for multiple stack and self-contained memory based on hardware measurements as shown covered by elongated region 1010 in the graph. Power well below 50 W/4 GB SRAM can be controlled by standard cooling and may not pose thermal issues. A low power of 14 W for each 4 GB can be achieved through architecture and 5 nm cell topology shown in the embodiments herein.

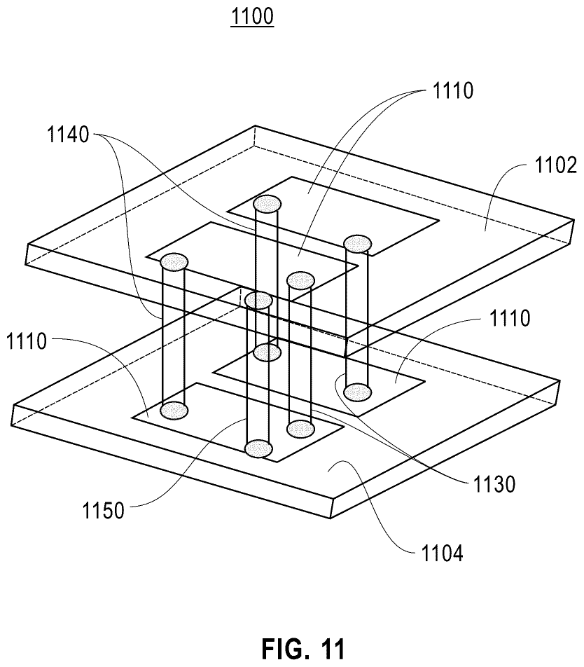

FIG. 11 depicts a view of a further 3D stacked memory device structure 1100 that includes stacked chiplet packages 1102, 1104 each with embedded SRAM memory devices 1110 that is built using the methods of the embodiments herein. The memory devices can include SRAM and NVM (e.g., MRAM, ReRAM, PCM etc. As shown in FIG. 11, the stacked chiplet packages 1100 with embedded SRAM memory devices 1110 are stacked and formed using the methods for forming the stacked 3-D structures described herein, including the flipping of the chiplet package and the hybrid bonding. In an embodiment, there can be oxide-oxide or dielectric bonding or C4 bonding. The stacked chiplet structure 1100 is formed to further include global conductive vias structures, e.g. through-silicon-vias (TSV) of copper material connected to convey specialized signals to/from the SRAM devices at a stacked chiplet at different levels in the manner as described herein. For example, there is provided one or more power vias 1130, e.g., for conveying VDD and VSS power signals, signal vias 1140, e.g., for conveying data/control signals, and thermal vias 1150, e.g., for controlling heat dissipation in the stacked structure.

While the present application has been particularly shown and described for preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory device comprising:
a two or more-layer memory die stack, the two or more-layer memory die stack comprising at least:
a first memory die having a first single layer of memory devices and conductors forming a backside power delivery network; and
a second memory die having a second single layer of memory devices and conductors forming a backside power delivery network;
wherein the second memory die is flipped in orientation, said first memory die and flipped second memory die are hybrid bonded together so that the backside power delivery network conductors of the first memory die are aligned with and directly bond to the backside power delivery network conductors of the second memory die.

2. The memory device of claim 1, wherein the first SRAM die comprises:
a frontside interlevel dielectric material (ILD) layer formed above the first single layer of memory devices, the frontside ILD material layer having one or more metallization levels of formed conductors, a metallization level conductor connected to a memory device for conducting signals to or from the memory device; and
a backside ILD layer formed below the single layer of memory devices, the backside ILD material layer having the backside power delivery network (BSPDN) conductors formed therein, the BSPDN conductors comprising one or more conductive power rail structures for receiving power signals for the memory device.

3. The memory device of claim 2, wherein the second memory die comprises:
a frontside ILD layer formed above the second single layer of memory devices, the frontside ILD material layer having one or more metallization levels of formed conductors, a metallization level conductor connected to an memory device for conducting signals to or from the memory device; and
a backside ILD layer formed below the single layer of memory devices, the backside ILD material layer having the BSPDN conductors formed therein, the BSPDN conductors comprising one or more conductive power rail structures for receiving power signals for the memory device,
wherein the conductive power rail structures of the backside ILD layer of the first memory die are bonded to corresponding conductive power rail structures of the backside ILD layer of the second memory die.

4. The memory device of claim 3, wherein each the first memory die and the second memory die comprises:
one or more global conductive via structures, each one or more global conductive via structures extending through from a bottom surface to a top surface of said first memory die and said second SRAM die, wherein at least a first global conductive via structure of the first memory die is hybrid bonded to a respective corresponding first global conductive via structure of the second memory die.

5. The memory device of claim 4, wherein
the first memory die of the two or more-layer memory die stack further comprises:
a top surface having exposed conductors of a top metallization level;
a carrier wafer formed above the top surface of the first memory die, the carrier wafer having a corresponding conductive through via structure aligned with and connecting a respective exposed conductor of the top metallization level, the corresponding conductive through via structure extending through the carrier wafer and a top surface of the conductive through via structure being exposed; and
the second memory die of the two or more-layer memory die stack further comprises:
a top surface having exposed conductors of a top metallization level; and
a corresponding solder material or C4 material bump aligned with and connecting a respective exposed conductor of the top metallization level.

6. The memory device of claim 5, wherein the memory device is a multiple-level vertically stacked memory structure, with each level of said multiple-levels comprising said two or more-layer memory die stack, and
the corresponding solder material or C4 material bump of a flipped second memory die of a two or more-layer memory die stack at one level of the multiple-level stacked memory structure are aligned with and electrically connected and bonded to an exposed top surface of a corresponding conductive through via structure at the carrier wafer of a first memory die of a two or more-layer memory die stack at an underlying adjacent level of the multiple-level stacked memory structure.

7. The memory device of claim 6, further comprising:
an interposer or carrier substrate having exposed conductors at a surface thereof, wherein at a bottommost level of the multiple-level stacked memory structure, a flipped second die of the two or more-layer memory die stack is hybrid bonded to and electrically connected with the exposed conductors of said interposer or carrier substrate, wherein the bonding uses corresponding solder material or C4 material bump aligned with and connecting a respective exposed conductor of the top metallization level to the exposed conductors.

8. A memory device comprising:
a first two-layer memory die stack comprising:
a first memory die having a single layer of memory devices, frontside conductive wires at a die surface for carrying signals, and conductors forming a backside power delivery network; and
a second memory die having a single layer of memory devices and conductors forming a backside power delivery network, the second memory die being flipped in orientation, wherein the first memory die and flipped second memory die being hybrid bonded together so that the backside power delivery network conductors of the first memory die are aligned with and directly bond to the backside power delivery network conductors of the flipped second memory die; and
a second two-layer memory die stack comprising:
a third memory die having a single layer of memory devices, and conductors forming a backside power delivery network; and
a fourth memory die having a single layer of memory devices, frontside conductive wires at a die surface for carrying signals, and conductors forming a backside power delivery network, the fourth memory die being flipped in orientation, wherein the third memory die and flipped fourth memory die are hybrid bonded together so that the backside power delivery network conductors of the third memory die are aligned with and directly bond to the backside power delivery network conductors of the flipped fourth memory die; and
the first two-layer memory die stack and second two-layer memory die stack being hybrid bonded to form a four (4)-layer memory die stack, the 4-layer memory die stack having the frontside conductive wires at a die surface of the first memory die of the first two-layer memory die stack bonded to the frontside conductive wires at a die surface of the flipped fourth memory die of the second two-layer memory die stack.

9. The memory device of claim 8, wherein each respective memory die of the first memory die, the second memory die, the third memory die and the fourth memory die comprises:
a frontside interlevel dielectric material (ILD) layer formed above the single layer of memory devices, the frontside ILD material layer having one or more metallization levels of formed conductors, a metallization level conductor connected to an memory device for conducting signals to or from the memory device; and
a backside ILD layer formed below the single layer of memory devices, the backside ILD material layer having the backside power delivery network (BSPDN) conductors formed therein, the BSPDN conductors comprising one or more conductive power rail structures for receiving power signals for the memory device,
wherein the conductive power rail structures of the backside ILD layer of the first memory die are bonded to corresponding conductive power rail structures of the backside ILD layer of the second memory die and the conductive power rail structures of the backside ILD layer of the third memory die are bonded to corresponding conductive power rail structures of the backside ILD layer of the fourth memory die.

10. The memory device of claim 9, wherein each respective memory die of the first memory die, the second memory die, the third memory die and the fourth memory die comprises:
one or more global conductive via structures, each one or more global conductive via structures extending through from a bottom surface to a top surface of the respective memory die, wherein at least a first global conductive via structure of the first memory die is hybrid bonded to a respective first global conductive via structure of the second memory die and at least a first global conductive via structure of the third memory die is hybrid bonded to a respective first global conductive via structure of the fourth memory die.

11. The memory device of claim 10, wherein the memory device is a multiple-level vertically stacked memory structure, with each level of said multiple-levels comprising said 4-layer memory die stack, wherein at adjacent levels including a first 4-layer memory die stack and an overlying adjacent second 4-layer memory die stack:
a top surface of the first 4-layer memory die stack comprises exposed conductors formed at a top metallization level of a frontside ILD layer of a third memory die of said second two-layer memory die stack of said first 4-layer memory die stack; and
a bottom surface of the overlying adjacent second 4-layer memory die stack comprises exposed conductors formed at a top metallization level of a frontside ILD layer of a flipped second memory die of said first two-layer memory die stack of said overlying adjacent second 4-layer memory die stack;
wherein said first 4-layer memory die stack and said second 4-layer memory die stack are hybrid bonded together so that the exposed conductors formed at the top metallization level of a frontside ILD layer of the third memory die of said first 4-layer memory die stack are aligned with and directly bond to the exposed conductors formed at the top metallization level of a frontside ILD layer of a flipped second memory die of said overlying adjacent second 4-layer memory die stack.

12. The memory device of claim 11, further comprising:
an interposer or carrier substrate having exposed conductors at a surface thereof, wherein at a bottommost level of the multiple-level stacked memory structure, a flipped second die of the two-layer memory die stack is hybrid bonded to and electrically connected with the exposed conductors of said interposer or carrier substrate, wherein the bonding uses a corresponding solder material bump or C4 material bump aligned with and connecting a respective exposed conductor of the top metallization level of the frontside ILD layer of the flipped second memory die to the exposed conductors of said interposer or carrier substrate.

13. A memory device comprising:
a two-layer memory die stack, the two-layer memory die stack comprising:
a first memory die having a single layer of memory devices, a frontside interlevel dielectric (ILD) layer above said single layer of memory devices, frontside conductive wires formed at multiple metallization levels in said frontside ILD layer for carrying signals, and conductors forming a backside power delivery network; and
a second memory die having a single layer of memory devices, a frontside interlevel dielectric (ILD) layer above said single layer of memory devices, frontside conductive wires formed at multiple metallization levels in said frontside ILD layer for carrying signals, and conductors forming a backside power delivery network, the second memory die being flipped in orientation,
the first memory die and flipped second memory die being hybrid bonded together so that the backside power delivery network conductors of the first memory die are aligned with and directly bond to the backside power delivery network conductors of the flipped second memory die.

14. The memory device of claim 13, wherein in each said first memory die and flipped second memory die, the frontside ILD layer formed above the single layer of memory devices comprises a metallization level conductor connected to an memory device for conducting signals to or from the memory device.

15. The memory device of claim 14, wherein each said first memory die and flipped second memory die comprises:
a backside ILD layer formed below the single layer of memory devices, the backside ILD material layer having the BSPDN conductors formed at multiple metallization levels therein, the BSPDN conductors comprising one or more conductive power rail structures for receiving power signals for powering the memory device, the backside ILD layer further comprising:
conductive contacts for connecting a conductive power rail structure to the memory device for delivering power signals to the memory device.

16. The memory device of claim 15, wherein each the first memory die and the flipped second memory die comprises:
one or more global conductive via structures, each one or more global conductive via structures extending through from a bottom surface to a top surface of said first memory die and said flipped second memory die, wherein at least a first global conductive via structure of the first memory die is hybrid bonded to a respective corresponding first global conductive via structure of the flipped second memory die.

17. The memory device of claim 16, wherein
the first memory die of the two-layer memory die stack further comprises:
a top surface having exposed conductors of a top metallization level;
a carrier wafer formed above the top surface of the first memory die, the carrier wafer having a corresponding conductive through via structure aligned with and connecting a respective exposed conductor of the top metallization level, the corresponding conductive through via structure extending through the carrier wafer and a top surface of the conductive through via structure being exposed; and
the flipped second memory die of the two-layer memory die stack further comprises:
a top surface having exposed conductors of a top metallization level; and
a corresponding solder material bump or C4 material bump aligned with and connecting a respective exposed conductor of the top metallization level.

18. The memory device of claim 17, wherein the memory device is a multiple-level vertically stacked memory structure, with each level of said multiple-levels comprising said two-layer SRAM die stack, and
the corresponding solder material or C4 material bump of a flipped second memory die of a two-layer memory die stack at one level of the multiple-level stacked memory structure are aligned with and electrically connected and bonded to an exposed top surface of a corresponding conductive through via structure at the carrier wafer of a first memory die of a two-layer memory die stack at an underlying adjacent level of the multiple-level stacked memory structure.

19. The memory device of claim 18, further comprising:
an interposer or carrier substrate having exposed conductors at a surface thereof, wherein at a bottommost level of the multiple-level stacked memory structure, a flipped second die of the two-layer memory die stack is hybrid bonded to and electrically connected with the exposed conductors of said interposer or carrier substrate, wherein the bonding uses corresponding solder material bump or C4 material bump aligned with and connecting a respective exposed conductor of the top metallization level to the exposed conductors.

20. The memory device of claim 16, wherein the memory device is a multiple-level vertically stacked memory structure, with each level of said multiple-levels comprising said two-layer memory die stack, wherein at adjacent levels:
the frontside conductive wires formed at a top metallization level in said frontside ILD layer of a first memory die of a first two-layer memory die stack are aligned with and electrically connected and bonded to corresponding exposed frontside conductive wires formed at a top metallization level in said frontside ILD layer of a flipped second memory die of a second two-layer memory die stack overlying and adjacent the first two-layer memory dies stack.
